(19) United States
(12) Patent Application Publication
(10) Pub. No.: US 2007/0229055 A1
(43) Pub. Date: Oct. 4, 2007

(54) Digital oscilloscope and method for displaying signal

(75) Inventor: Yoshihiro Nishida, Akishima-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/727,939

(22) Filed: Mar. 29, 2007

(30) Foreign Application Priority Data
Mar. 31, 2006 (JP) 2006-100781

(51) Int. Cl. G01R 23/16; G01R 27/02

(52) U.S. Cl. 324/76.12

(57) ABSTRACT

A measured value processing circuit records measured values for a predetermined number of repeated patterns converted by an A/D converter, in a measured value memory. A calculation section calculates standard deviations of measured values for the predetermined number of repeated patterns obtained at corresponding sample times of predetermined period. A waveform processing section uses the standard deviations determined by the calculation section to generate a waveform corresponding to the input signal. A display control section displays the waveform generated by the waveform processing section, in a display section. The present invention reduces the amount of noise displayed on a display screen. A digital oscilloscope can thus display a waveform that allows the quality of an input signal to be easily evaluated.

### CROSS-REFERENCE TO RELATED APPLICATIONS

This application is based upon and claims the benefit of priority from Japanese Patent Application No. 2006-100781, filed Mar. 31, 2006, the entire contents of which are incorporated herein by reference.

### BACKGROUND

1. Field

The present invention relates to a digital oscilloscope, and more specifically, to a technique for partly removing a noise component to display an input signal waveform.

2. Description of the Related Art

A digital oscilloscope converts an analog measured waveform into a digital signal to load the digital signal into a memory as waveform data, and displays the waveform data in a display section via a display processing section. The digital oscilloscope is widely used as waveform measuring and displaying means for research and development, quality control, and maintenance in various fields.

With conventional digital signals, a large difference between their H (High) and L (Low) levels virtually prevents wave observation from being affected by noise from a measuring instrument or the like. However, recent high-speed differential signals of several GHz have only a small difference between the H level and the L level, for example, about 150 mV. Consequently, noise from a measuring instrument or noise generated at a signal observation point may be superimposedly displayed on a displayed waveform, making the object of the measurement unclear.

Averaging an input signal allows the display of a waveform free from such a noise component. Jpn. Pat. Appln. KOKAI Publication No. 2005-69904 discloses a real-time addition circuit and a measured waveform averaging apparatus which reduce the time required to execute an averaging process to enable a high-speed waveform averaging process.

A signal obtained by averaging an input signal as in the conventional art does not make it possible to determine whether or not the input signal is appropriate, that is, to determine its quality.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a diagram showing the configuration of an evaluation system using a digital oscilloscope 100 to which the present invention is applied;

FIG. 2 is a block diagram schematically showing the configuration of the oscilloscope 100;

FIG. 3 is a diagram of an input signal waveform displayed with a circuit board 30 in FIG. 1 powered off;

FIG. 4 is a diagram of an example in which a repeated signal waveform of binary 7-bit data output as a digital signal is sampled as an input signal Vi;

FIG. 5A is a diagram showing only an initial waveform of the repeated waveform in FIG. 4, with a time axis enlarged, and FIG. 5B is a diagram showing an example of a waveform obtained by a statistical process in accordance with a first embodiment of the present invention on the basis of the waveform in FIG. 5A;

FIG. 6 is a flowchart showing operations of the oscilloscope in accordance with the first embodiment of the present invention;

FIG. 7 is a diagram showing an example of measured values determined by sampling a waveform such as the one shown in FIG. 5A;

FIG. 8 is a diagram illustrating a process for determining a standard deviation;

FIG. 9 is a diagram showing the distribution (normal distribution curve) of sample values obtained at a sample time tn;

FIG. 10 is a diagram showing an example of two statistically processed waveforms W2 and W3 superimposedly displayed by a waveform superimposition circuit 10a; and

FIG. 11 is a diagram showing an example in which a waveform signal such as the one shown in FIG. 4 is displayed in an eye pattern.

### DETAILED DESCRIPTION

Various embodiments according to the invention will be described hereinafter with reference to the accompanying drawings. In general, according to one embodiment of the invention, there is provided a digital oscilloscope comprising an analog to digital conversion section which samples an input signal of a repeated pattern and subjects the input signal to an analog to digital conversion; a section which records measured values for a predetermined number of repeated patterns converted by the analog to digital conversion section; a calculation section which calculates standard deviations of measured values for the predetermined number of repeated patterns obtained at corresponding sample times of predetermined period in the repeated patterns; a generation section which uses the standard deviation for each sample time determined by the calculation section to generate a waveform corresponding to the input signal; and a display section which displays the waveform generated by the generation section.

The digital oscilloscope decreases the display of noise, making it possible to easily determine whether or not the waveform is appropriate.

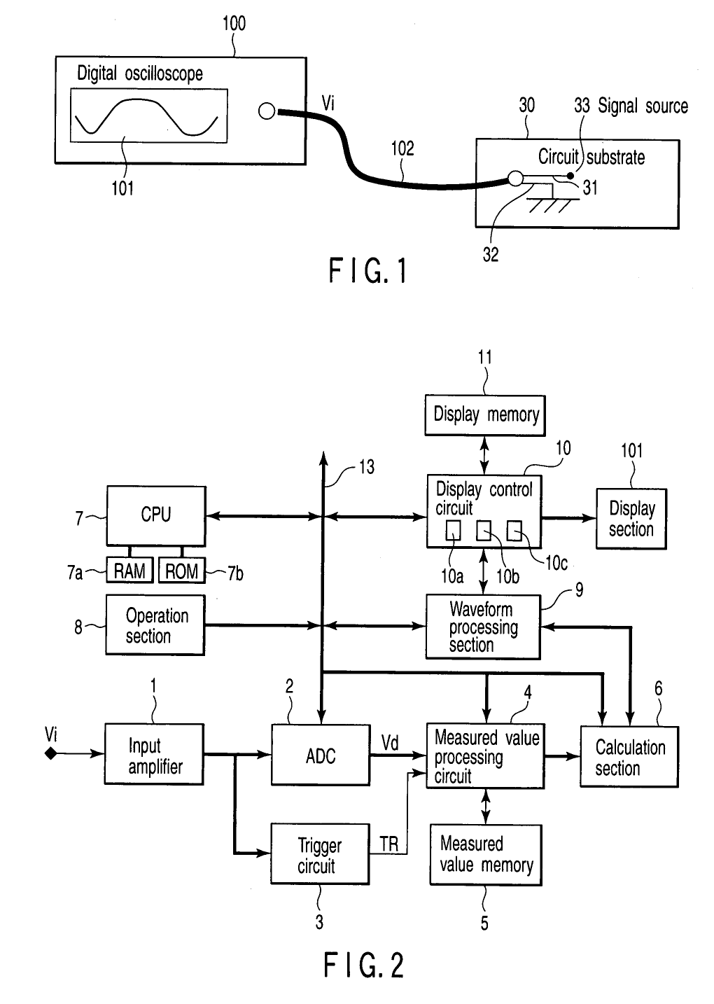

FIG. 1 shows the configuration of an evaluation system using a digital oscilloscope 100 to which the present invention is applied.

A circuit board 30 is an electronic circuit unit comprising PCB (Printed Circuit Board) on which electronic circuit parts such as LSIs including CPU and memories, resistors, and capacitors are mounted. The oscilloscope 100 is supplied with the voltage between a PCB signal line 31 and a ground pattern 32 via a cable 102. The signal line 31 is supplied with a signal Vi of a repeated waveform from a signal source 33 such as CPU.

FIG. 2 is a block diagram schematically showing the configuration of the oscilloscope 100.

Voltage amplitude of input signal Vi is adjusted by an input amplifier 1 and is then guided to an A/D converter 2, which then converts the voltage level of the signal into a digital value Vd at a predetermined sample rate. A measured value processing circuit 4 writes the input digital value Vd to a measured value memory 5 at a sample rate based on a time axis setting in response to a trigger condition establishment signal TR from a trigger circuit 3. A calculation section 6 in accordance with the present embodiment calculates, for example, an average value or a value a (standard deviation) on the basis of the data written to the measured value memory 5. Display voltage range based on σ is thus determined for each sample time. The operation of the calculation section 6 will be described in detail.

The display voltage range data is converted into waveform data by a waveform processing section 9. The waveform data is then transferred to a display control circuit 10. The display control circuit 10 then stores the input waveform data in a display memory 11 and drives a display device 11 such as a liquid crystal on the basis of the data to display a statistically processed waveform on the display device 11.

CPU 7 uses RAM 7a as a work area to generally control the apparatus in accordance with various control programs stored in ROM b. An operation section 8 serves as an interface between an operator and the oscilloscope 100. CPU 7 communicates with the operation section 8, measured value processing circuit 8, and display control circuit 9 via a control bus 13. The measured value processing circuit 4, calculation section 6, waveform processing section 9, and display control circuit 10 are configured into hardware using individual electronic circuits. However, these may be configured as software using program steps.

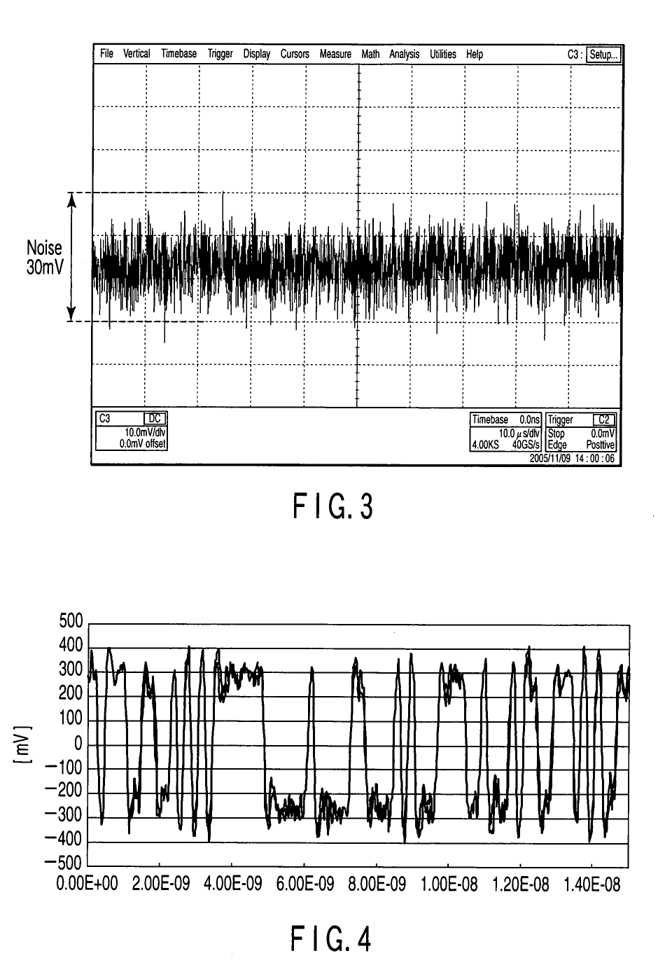

FIG. 3 shows an input signal waveform displayed with the circuit board 30 in FIG. 1 powered off. Even if no signal is supplied to the signal line 31 as in this case, noise of about 30 mV is displayed for the signal line. If such noise is mixed into, for example, a digital signal of amplitude 150 mV, it is difficult to accurately observe the signal waveform. The embodiment of the present invention prevents such noise from being displayed on a display screen 101 of the oscilloscope 100. This facilitates accurate signal waveform observations or comparisons of signal waveforms.

FIG. 4 shows an example in which a repeated signal waveform of binary 7-bit data output as a digital signal is sampled as an input signal Vi. The axis of ordinate shows voltage (V), while the axis of abscissa shows time (seconds). This figure generally shows a waveform of period 15 ns.

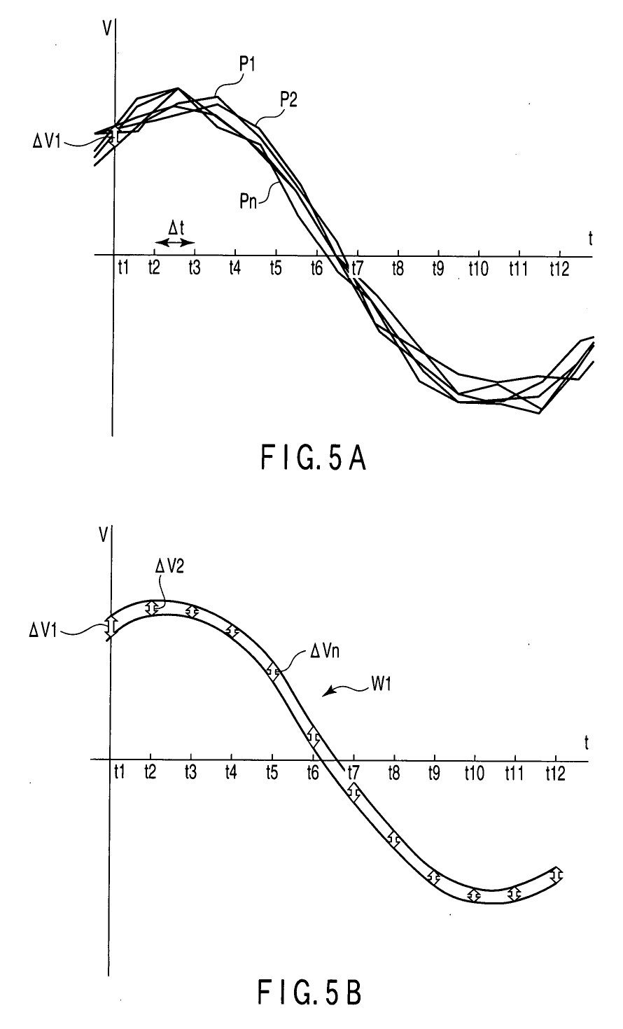

For simplification, only the initial part of the repeated waveform in FIG. 4 is shown with the time axis enlarged. FIG. 5A shows the resulting waveform. A pattern P1 is the first measured waveform. A pattern P2 is the second measured waveform. A pattern Pn is the nth measured waveform. Here, the input signal Vi is sampled at a sampling period Δt.

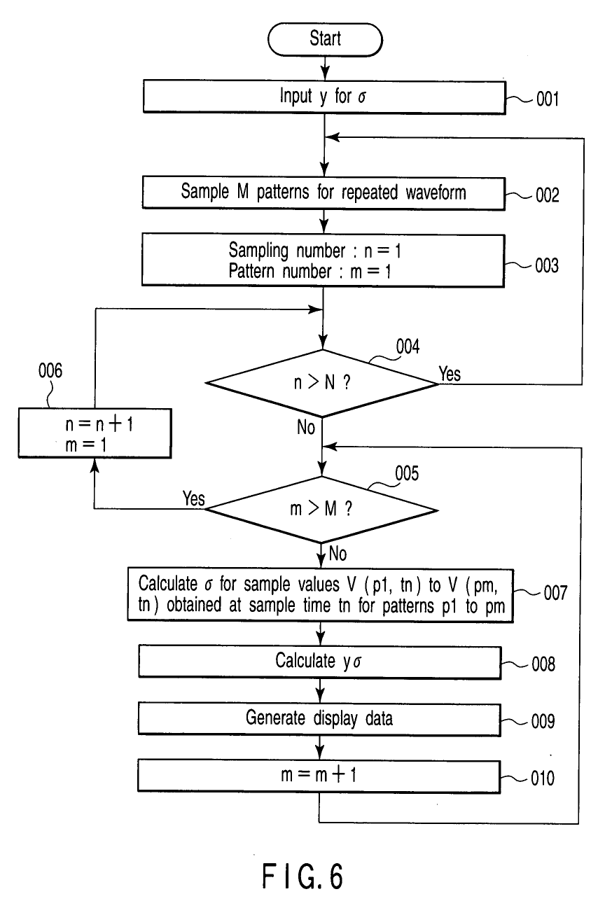

Now, a detailed description will be given of operation of the oscilloscope 100 in accordance with an embodiment of the present invention. FIG. 6 is a flowchart showing the operation of the oscilloscope 100.

First, an operator inputs a number y for σ via an operation section 8. The number is then supplied to the calculation section 6 (block 001). As described below, the number y for σ is used by the calculation section to determine the line width of a displayed waveform.

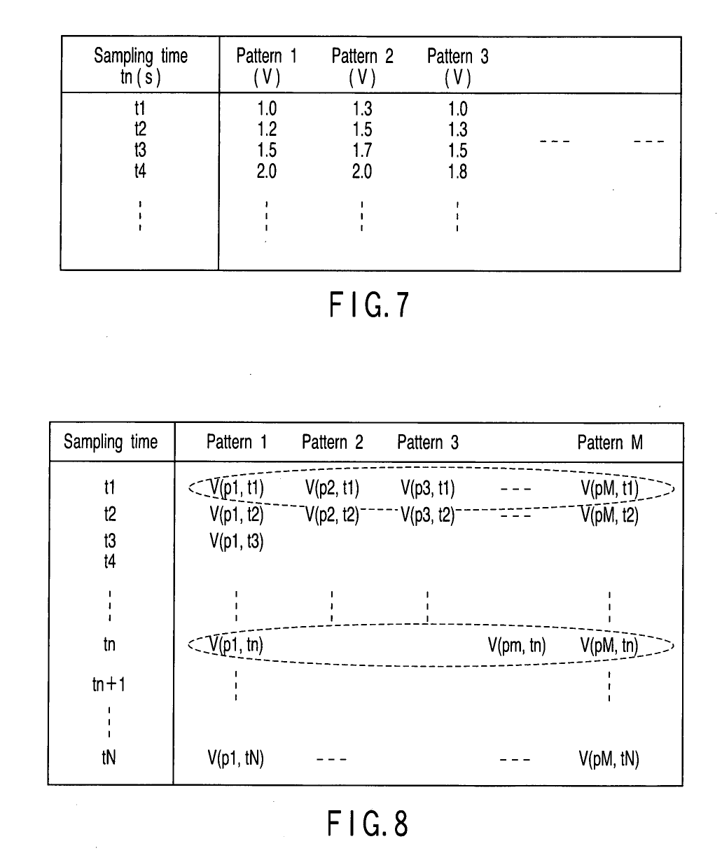

As shown in block 002, the measured value processing circuit 4 samples M patterns of a repeated waveform. At this time, the measured value processing circuit 4 stores measured values supplied by the A/D converter 2 at the sampling period Δt, in the measured value memory 5 for each pattern as shown in FIG. 7. In FIG. 7, for simplification, the amplitude of each pattern is shown as a voltage value (V).

The calculation section 6 calculates the dispersion of the measured values at each sample time tn on the basis of the measured values stored in the measured value memory 5.

As shown in FIG. 8, the amplitude of the pattern p1 at a sample time t1 is defined as V (p1, t1). The amplitude of the pattern p1 at a sample time t2 is defined as V (p1, t2). Similarly, the amplitude of a pattern pm at a sample time tn is defined as V (pm, tn).

As shown in block 003, the calculation section 6 substitutes 1 into the sampling number n and 1 into the pattern number m. The calculation section 6 determines whether or not the sampling number n is larger than the maximum value N of the sampling number (block 004). If the sampling number n is smaller than the maximum value N (NO), the calculation section 6 determines whether or not the pattern number m is larger than the maximum value M of the pattern number (block 005).

If the pattern number m is smaller than the maximum value M (NO in block 005), processing ion blocks 007 to 001 described below is repeated and the standard deviation σ or the like at the sample time t1 is calculated using sample values (measured values) V (p1, t1) to V (pM, t1).

If the pattern number m is larger than the maximum value M (YES in block 005), n+1 is substituted into the sampling number n and 1 is substituted into the pattern number m (block 006). Block 004 is executed again, and if the sampling number n is smaller than the maximum value N of the sampling number (NO), block 005 is executed again. In block 005, if the pattern number m is smaller than the maximum value M (NO), the processing in blocks 007 to 010, described below, is repeated. The standard deviation a or the like at the sample time t2 is calculated using sample values V (p1, t2) to V (pM, t2). In this manner, the standard deviation σ or the like at the sample time tn is calculated in blocks 007 to 010 using sample values V (p1, tn) to V (pM, tn).

Once the sampling deviations σ or the like at the sample times t1 to tN are calculated (YES in block 004), the flow returns to block 002 to sample new M patterns of the repeated waveform. The calculation section 6 then repeats the processing in block 003 to 010 as previously described.

Now, a detailed description will be given of a loop process in blocks 007 to 010. In block 007, the calculation section 6 calculates the standard deviation σ at the sample time tn. That is, the calculation section 6 calculates σ based on a general formula for the standard deviation from the sample values V (p1, tn) to V (pm, tn) for the patterns p1 to pm at the sample time tn as follows.

$$Standard deviation σ = \sqrt{\frac{( \begin{matrix}Sum of data item values each obtained \\ by {( sample value - average value )}^{2}\end{matrix} )}{The number of samples}}$$

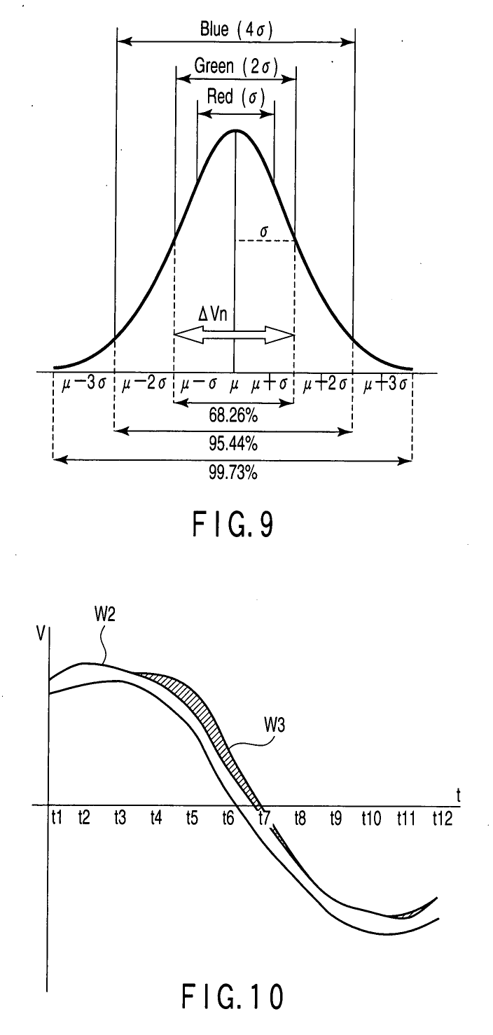

FIG. 9 is a diagram showing the distribution of (normal distribution curve) of the sample value at the sample value tn. An increase in the number of samples makes the shape of the distribution more similar to the normal distribution curve. Thus, about 68% of all the sample values are within the range of the average value μ±σ, and about 95% of them are within the range of the average value μ±2σ. When block 007 is executed for the first time, the standard deviation σ is the sample value itself.

Then, the calculation section 6 multiplies σ calculated in block 007 by the number y input in block 001 to calculate yσ (block 008). A voltage range ΔVn (n=1, 2, . . . ) shown in FIG. 5B shows an example of yσ determined by the calculation using the waveform value in FIG. 5A.

The waveform processing section uses the calculated average value, yσ, and the like to generate waveform display data as a statistically processed waveform as shown in block 009. As shown by a solid line in FIG. 5B, the statistically processed waveform is similar to the curve W1 of the voltage range ΔVn. The display control circuit 10 stores the statistically processed waveform provided by the waveform processing section 9, in the display memory 11. The curve W1 is displayed in the display section 101.

The present embodiment can statistically processes an input signal as described above to display a waveform with low noise. An example of a digital oscilloscope with low noise is a sampling oscilloscope that samples periodical voltages for a given time to display a waveform with a period. However, a real time oscilloscope, to which the present application is applied, can also provide a waveform with low noise. When the next M patterns are sampled for a statistical process as in block 002, the continuity of the displayed waveform is maintained by executing the process by using the already determined σ.

The display control circuit 10 has a waveform superimposition circuit 10a. The waveform superimposition circuit 10a statistically processes different input repeated waveforms as previously described to store the resulting two waveforms in the display memory 11, while supperimposedly displaying the two waveforms in the display section 11.

FIG. 10 shows an example of two statistically processed waves W2 and W3 superimposedly displayed by the waveform superimposition circuit 10a. Thus superimposing statistically processed waveforms on each other clarifies a difference in measured value distribution between the two waveforms.

The display control circuit 10 has a frequency distribution display section 10b. The frequency distribution display section 10b displays the distribution so that its color varies depending on the frequency of the measured value. For example, as shown in FIG. 9, the range σ, the range of σ to 2σ, and the range of 2σ to 4σ, which are centered at the average value μ, are displayed in red, green, and blue, respectively. This display makes the distribution of measured values more easily understood. The values σ, 2σ, and the like (voltage range) are determined by the calculation section 6.

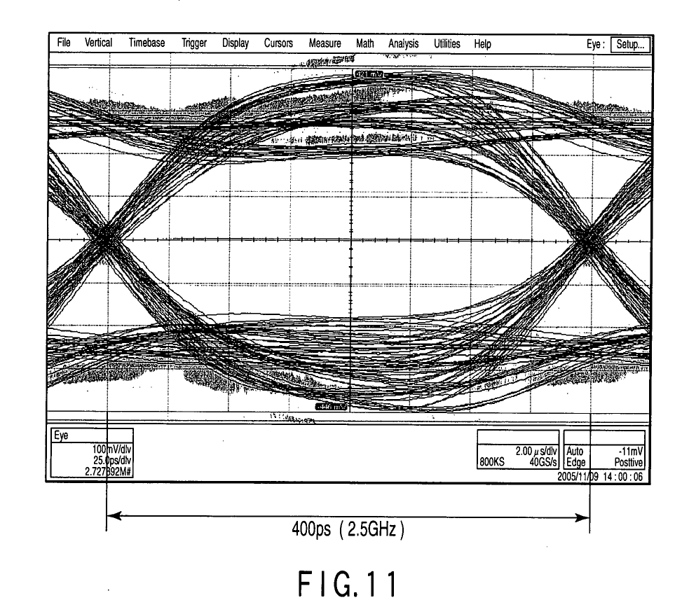

The display control circuit 10 has an eye pattern display section 10c that displays a statistically processed waveform provided by the waveform processing section 9, in an eye pattern. FIG. 11 shows an example of an eye pattern display of a waveform signal such as the one shown in FIG. 4. Also with such an eye pattern display, a waveform statistically processed as described above enables the distribution of measured values to be clarified.

As described above, the embodiment of the present invention displays the range σ, 2σ and the like for a measured repeated signal. This prevents the display of noise, making it possible to easily determine whether or not the waveform is appropriate. The embodiment also makes it possible to compare a plurality of different signal waveforms to easily determine the difference among them.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A digital oscilloscope comprising:
an analog to digital conversion section which samples an input signal of a repeated pattern and subjects the input signal to an analog to digital conversion;
a section which records measured values for a predetermined number of repeated patterns converted by the analog to digital conversion section;
a calculation section which calculates standard deviations of measured values for the predetermined number of repeated patterns obtained at corresponding sample times of predetermined period in the repeated patterns;
a generation section which uses the standard deviation for each sample time determined by the calculation section to generate a waveform corresponding to the input signal; and
a display section which displays the waveform generated by the generation section.

2. The digital oscilloscope according to claim 1, wherein when the standard deviation calculated by the calculation section is defined as σ, the generation section statistically processes the input signal to generate a curve indicating a waveform and having a voltage width based on σ and centered at an average value of the measured values obtained at the sample times of predetermined period in the repeated patterns.

3. The digital oscilloscope according to claim 2, wherein the display section stores the statistically processed waveform provided by the generation section and superimposedly displays two waveforms stored at different times.

4. The digital oscilloscope according to claim 2, wherein the display section has a section which displays the statistically processed waveform provided by the generation section, in an eye pattern.

5. The digital oscilloscope according to claim 2, wherein the calculation section provides a signal indicating at least two frequency distribution ranges of measured values obtained at the sample times,
the generation section generates waveforms showing the two frequency distribution ranges, and
the display section displays the waveforms showing the two frequency distribution ranges, in different colors.

6. A method for displaying a signal, the method comprising:
sampling an input signal of a repeated pattern and subjecting the input signal to an analog to digital conversion;
recording measured values for a predetermined number of repeated patterns subjected to the analog to digital;
calculating standard deviations of measured values for the predetermined number of repeated patterns obtained at corresponding sample times of predetermined period in the repeated patterns;
using the standard deviation for each sample time determined by the calculation section to generate a waveform corresponding to the input signal; and
displaying the generated waveform.

7. The method according to claim 6, wherein when the standard deviation calculated by the calculation section 9 is defined as σ, the generating the waveform includes statistically processing the input signal to generate a curve indicating a waveform and having a voltage width based on σ and centered at an average value of the measured values obtained at the predetermined sample time intervals.

8. The method according to claim 7, wherein the displaying the waveform includes storing the statistically processed waveform and superimposedly displaying two waveforms stored at different times.
